(19) United States
(12) Patent Application Publication
(10) Pub. No.: US 2026/0190794 A1
(43) Pub. Date: Jul. 2, 2026

(54) LIGHT EMITTING DISPLAY APPARATUS

(71) Applicant: LG Display Co., Ltd., Seoul (KR)

(72) Inventors: Sooyoun KIM, Paju-si (KR); Chiwan KIM, Paju-si (KR); SiHyun KIM, Paju-si (KR)

(73) Assignee: LG Display Co., Ltd., Seoul (KR)

(21) Appl. No.: 19/191,468

(22) Filed: Apr. 28, 2025

(30) Foreign Application Priority Data
Dec. 30, 2024 (KR) 10-2024-0201451

(51) Int. Cl. H10K 59/80; H10K 59/40

(52) U.S. Cl. CPC H10K 59/874; H10K 59/40; H10K 59/873

(57) ABSTRACT

A light emitting display apparatus according to one or more examples may include a substrate; a display area, a first non-display area surrounding the display area, and a bending area extended from at least a portion of the first non-display area; a pixel part having a plurality of pixels in the display area; a touch sensor layer over the pixel part; and a getter layer configured at the bending area. The getter layer may comprise a plurality of first getter patterns, and a plurality of second getter patterns configured between the plurality of first getter patterns and made of a material different from the plurality of first getter patterns.

### CROSS-REFERENCE TO RELATED APPLICATION

This application claims the benefit of and priority to Korean Patent Application No. 10-2024-0201451 filed on Dec. 30, 2024, the entirety of which is incorporated herein by reference for all purposes as if fully set forth herein.

### BACKGROUND

### 1. Technical Field

The present disclosure relates to a light emitting display apparatus.

### 2. Description of the Related Art

A light emitting display apparatus is a self-emitting display apparatus, and unlike a liquid crystal display apparatus, the light emitting display apparatus may be fabricated at a lightweight and slim size as it does not need an additional light source. In addition, the light emitting display apparatus is favorable in view of power consumption due to low voltage driving and also is excellent for a color realization, a response speed, a viewing angle, and a contrast ratio, whereby the light emitting display apparatus has been studied as a display for next generation.

In the light emitting display apparatus, a thin film transistor, a light emitting device layer, and an encapsulation layer are formed on base substrate. The light emitting device layer is connected to the thin film transistor. The encapsulation layer includes an inorganic film and an organic film, and covers the thin film transistor and the light emitting device layer.

The light emitting display apparatus may be implemented as a flexible light emitting display apparatus.

When the light emitting display apparatus is implemented as a flexible light emitting display apparatus, cracks may occur in the inorganic film disposed at the outermost portion during the bending of the display apparatus, and moisture may penetrate into the display panel through the organic film.

The above-described background is possessed by the inventor of the application for deriving the disclosure, or is technology information that has been acquired in deriving the disclosure. The above-described background is not necessarily known technology disclosed to the general public before the application of the disclosure. Thus, description of the related art should not be assumed to be prior art merely because it is mentioned in or associated with this section. The description of the related art includes information that describes one or more aspects of the subject technology, and the description in this section does not limit the invention.

### SUMMARY

One or more aspects of the present disclosure are directed to providing a light emitting display apparatus capable of preventing hydrogen or moisture from penetrating into the display panel.

One or more aspects of the present disclosure are directed to providing a light emitting display apparatus with improved reliability by preventing hydrogen or moisture from penetrating into the display panel.

Additional advantages and features of the disclosure will be set forth in part in the description which follows and in part will become apparent to those having ordinary skill in the art upon examination of the following or may be learned from practice of the disclosure. The aspects and other advantages of the disclosure may be realized and attained by the structure particularly pointed out in the written description and claims hereof as well as the appended drawings.

To achieve these and other advantages and aspects of the present disclosure, as embodied and broadly described herein, in one or more aspects, a light emitting display apparatus may comprise a substrate; a display area, a first non-display area surrounding the display area, and a bending area extended from at least a portion of the first non-display area; a pixel part having a plurality of pixels in the display area; a touch sensor layer over the pixel part; and a getter layer configured at the bending area. The getter layer may comprise a plurality of first getter patterns, and a plurality of second getter patterns configured between the plurality of first getter patterns and made of a material different from the plurality of first getter patterns.

Specific details according to various examples of the present disclosure other than the means for solving the above-mentioned problems are included in the description and drawings below.

According to one or more aspects of the present disclosure, since the light emitting display apparatus includes a getter layer configured in a bending area, hydrogen or moisture may be prevented from penetrating into the display panel.

According to one or more aspects of the present disclosure, the light emitting display apparatus prevents hydrogen or moisture from penetrating into the display panel, thereby preventing corrosion of thin film transistors and metal lines (or wires), thereby improving the reliability of the light emitting display apparatus.

According to one or more aspects of the present disclosure, since the light emitting display apparatus includes a getter layer configured in a bending area, the lifespan of the light-emitting display apparatus may be improved, and thus low-power driving may be implemented.

The details of the present disclosure described in technical problem, technical solution, and advantageous effects do not specify essential features of claims, and thus, the scope of claims is not limited by the details described in detailed description of the disclosure.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a plan view illustrating a light emitting display apparatus according to an embodiment of the present disclosure.

FIG. 2 is a cross-sectional view illustrating a light emitting display apparatus according to an embodiment of the present disclosure.

FIG. 3 is an enlarged view illustrating region ‘A’ illustrated in FIG. 2.

FIG. 4 is an enlarged view illustrating region ‘B’ illustrated in FIG. 1.

FIG. 5 is an enlarged view illustrating an example of region ‘C’ illustrated in FIG. 4.

FIG. 6 is a cross-sectional view taken along line I-I′ shown in FIG. 5.

FIG. 7 is an enlarged view illustrating another example of region ‘C’ illustrated in FIG. 4.

FIGS. 8A and 8B are diagrams illustrating the results of corrosion evaluation of the bending area of the light emitting display apparatus according to the experimental example and the embodiment of the present disclosure.

FIGS. 9A and 9B are diagrams illustrating the results of evaluation of bending stress in a bending area of a light emitting display apparatus according to an experimental example and an embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and convenience.

### DETAILED DESCRIPTION

Reference is now made in detail to aspects of the present disclosure, examples of which may be illustrated in the accompanying drawings. In the following description, when a detailed description of well-known functions, structures or configurations may unnecessarily obscure aspects of the present disclosure, a detailed description of such known functions or configurations may have been omitted for brevity. Further, repetitive descriptions may be omitted for brevity. The progression of processing steps and/or operations described is a non-limiting example.

Advantages and features of the present disclosure, and implementation methods thereof, are clarified through the aspects described with reference to the accompanying drawings. The present disclosure may, however, be embodied in different forms and should not be construed as limited to the example aspects set forth herein. Rather, these example aspects are examples and are provided so that this disclosure may be thorough and complete to assist those skilled in the art to understand the inventive concepts without limiting the protected scope of the present disclosure.

A shape, a size, a ratio, an angle, and a number disclosed in the drawings for describing aspects of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. When “comprise”, “have”, and “include” described in the present disclosure are used, another part may be added unless “only” is used. The terms of a singular form may include plural forms unless referred to the contrary. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In construing an element, the element is construed as including an error or tolerance range although there is no explicit description of such an error or tolerance range.

In describing a position relationship, for example, when a position relation between two parts is described as, for example, “on”, “over”, “under”, and “next”, one or more other parts may be disposed between the two parts unless a more limiting term, such as “just” or “direct(ly)” is used. In the description of aspects, when a structure is described as being positioned “on or above or over” or “under or below” another structure, this description should be construed as including a case in which the structures contact each other as well as a case in which a third structure is disposed therebetween.

In describing a time relationship, for example, when the temporal order is described as, for example, “after”, “subsequent”, “next”, and “before”, or the like, a case that is not continuous may be included unless a more limiting term, such as “just”, “immediate(ly)”, or “direct(ly)” is used.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first”, “second”, “A”, “B”, “(a)”, “(b)”, etc. may be used. These terms are intended to identify the corresponding elements from the other elements, and basis, order, or number of the corresponding elements should not be limited by these terms. The expression that an element or layer is “connected”, “coupled”, or “adhered” to another element or layer means the element or layer may not only be directly connected or adhered to another element or layer, but also be indirectly connected or adhered to another element or layer with one or more intervening elements or layers “disposed” or “interposed” between the elements or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various aspects of the present disclosure may be partially or overall coupled to or combined with each other, and may be variously inter-operated with each other and driven technically as those skilled in the art may sufficiently understand. Aspects of the present disclosure may be carried out independently from each other, or may be carried out together in co-dependent relationship.

The light emitting display apparatus according to an embodiment of the present disclosure may be a display panel, or a flexible display panel, but embodiments of the present disclosure are not limited thereto. For example, the light emitting display apparatus according to an embodiment of the present disclosure may include a set electronic apparatus or a set device (or a set apparatus) such as a notebook computer, a television, a computer monitor, an equipment apparatus including an automotive apparatus or another type apparatus for vehicles, or a mobile electronic apparatus such as a smartphone or an electronic pad, which is a complete product (or a final product) including a display panel.

Hereinafter, aspects of the present disclosure will be described in detail with reference to the accompanying drawings. For convenience of description, a scale of each of elements illustrated in the accompanying drawings differs from a real scale, and thus, is not limited to a scale illustrated in the drawings.

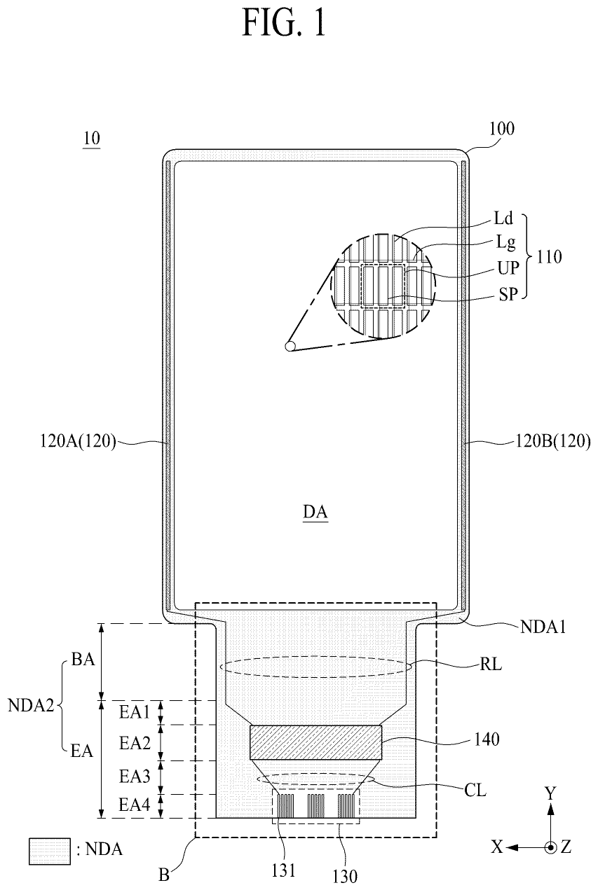

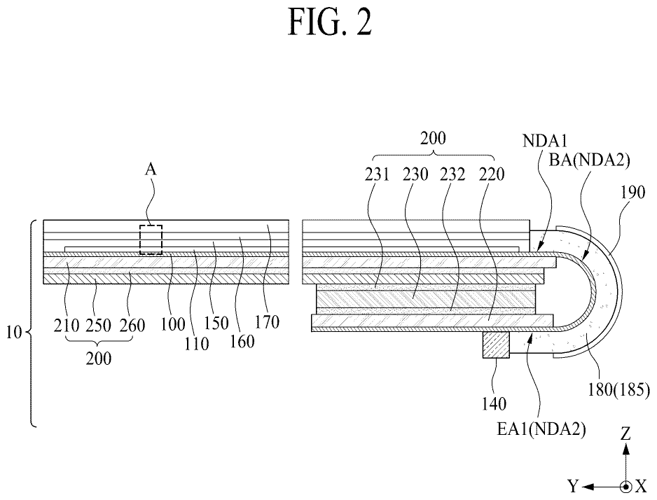

FIG. 1 is a plan view illustrating a light emitting display apparatus according to an embodiment of the present disclosure. FIG. 2 is a cross-sectional view illustrating a light emitting display apparatus according to an embodiment of the present disclosure.

Referring to FIGS. 1 and 2, the light emitting display apparatus (or display panel) 10 according to an embodiment of the present disclosure may have a shape where a portion thereof is bent as illustrated in FIG. 2. The light emitting display apparatus (or display panel) 10 according to an embodiment of the present disclosure may be a flexible light emitting display apparatus with a portion that is bent. FIG. 1 illustrates a shape where the light emitting display apparatus (or the display panel) 10 according to an embodiment of the present disclosure is not bent.

The light emitting display apparatus (or a display panel) 10 according to an embodiment of the present disclosure may include a substrate 100 which includes a display area DA and a non-display area NDA (NDA1 and NDA2).

The substrate 100 may be a base member or a base substrate for supporting or forming various elements of the light emitting display apparatus 10. The substrate 100 may be configured as a material having flexibility. The substrate 100 according to an embodiment of the present disclosure may be configured as a plastic material such as polyimide or the like, but embodiments of the present disclosure are not limited thereto.

The display area DA may be an area which displays an image. For example, the display area DA may be a display part, an active area, or an active part.

The non-display area NDA may be an area which does not display an image. The non-display area NDA may be a peripheral region of the display area DA. For example, the non-display area NDA may be implemented to surround the display area DA. For example, the non-display area NDA may include an edge portion of the substrate 100. For example, the non-display area NDA may be a non-display part, an inactive region, an inactive part, a peripheral part, or a peripheral region. For example, the display area DA may be a flat region or a flat portion.

The non-display area NDA according to an embodiment of the present disclosure may include a first non-display area NDA1 and a second non-display area NDA2.

The first non-display area NDA1 may be implemented to surround the display area DA. For example, the first non-display area NDA1 may include a region which extends from the display area DA. For example, the first non-display area NDA1 may include a region which extends to have a certain width from each side of the display area DA. For example, the first non-display area NDA1 may be a flat region or a flat portion.

The first non-display area NDA1 may include a pair of short-side regions parallel to a first direction X and a pair of long-side regions parallel to a second direction Y intersecting with the first direction X. For example, the pair of long-side regions of the first non-display area NDA1 may be folded or bent toward a rear surface of the display area DA, and thus, the display apparatus may decrease in bezel width of the long-side region.

The second non-display area NDA2 may include a region which extends from one side of the first non-display area NDA1. The second non-display area NDA2 may include a region which extends from at least a portion of one short side of the first non-display area NDA1 to have a certain length along the second direction Y. For example, the second non-display area NDA2 may extend from a center portion of the one short side of the first non-display area NDA1 to have a certain width and a certain length. For example, a width of the second non-display area NDA2 parallel to the first direction X may be smaller than a width of the display area DA or a width of the first non-display area NDA1 parallel to the first direction X. For example, the second non-display area NDA2 may be an extension portion, a protrusion portion, an enlarged portion, a routing portion, a signal transfer portion, a protrusion region, an enlarged region, a routing region, or a signal transfer region.

The second non-display area NDA2 according to an embodiment of the present disclosure may include a bending area BA and an extension area EA.

The bending area BA may include a region which extends from one side of the first non-display area NDA1. The bending area BA may be bent from the one side of the first non-display area NDA1 to have a certain curvature. For example, the bending area BA may be bent toward a rear surface of the first non-display area NDA1 (or a substrate 100) from the one side of the first non-display area NDA1, but embodiments of the present disclosure are not limited thereto. For example, the bending area BA may be bent from the one side of the first non-display area NDA1 to have a semicircular shape. For example, the bending area BA may be a non-planar portion, a non-flat portion, a bending portion, a curved portion, a curvature portion, a bending line portion, or a bending line area.

The extension area EA may extend from at least a portion of one short side of the first non-display area NDA1. The extension area EA may extend along the second direction Y from the bending area BA. The extension area EA may overlap with the display area DA. For example, the extension area EA may be disposed under a rear surface of the substrate 100 and may face the rear surface of the substrate 100. For example, the extension area EA may overlap with the first non-display area NDA1 and a portion of the display area DA adjacent to the first non-display area NDA1.

The extension area EA may include one or more extension areas EA1 to EA4 which extend along the second direction Y from the bending area BA. For example, the extension area EA may include first to fourth extension areas EA1 to EA4 which extend along the second direction Y from the bending area BA.

The first extension area EA1 may extend from the bending area BA. For example, the first extension area EA1 may be a circuit area, a line area, a signal transfer region, or a routing area.

The second extension area EA2 may extend from the first extension area EA1. For example, the second extension area EA2 may be a circuit area, a circuit arrangement area, a circuit mount area, or a chip mount area.

The third extension area EA3 may extend from the second extension area EA2. For example, the third extension area EA3 may be a circuit area, a line area, or a signal transfer area.

The fourth extension area EA4 may extend from the third extension area EA3. For example, the fourth extension area EA4 may be a circuit coupling portion, a circuit connection portion, a circuit coupling area, a circuit connection area, a pad area, or a signal input/output area.

The light emitting display apparatus (or the display panel) 10 according to an embodiment of the present disclosure may further include a pixel part 110, a gate driving circuit 120, a pad part 130, and a display driving circuit 140.

The pixel part 110 may be implemented at the display area DA of the substrate 100 and may display a black image or a color image. For example, the pixel part 110 may be a pixel layer, a pixel array, a pixel array layer, or a pixel array part.

The pixel part 110 may include a plurality of pixels UP disposed at the display area DA. The plurality of pixels UP may be respectively implemented at pixel regions provided by a plurality of gate lines Lg and a plurality of data lines Ld.

The pixel part 110 may be configured to include a light emitting device having an emission structure (or a light emitting structure). For example, the emission structure may include a light emitting layer (or an organic light emitting layer), but embodiments of the present disclosure are not limited thereto and the emission structure may include an inorganic light emitting layer (or an inorganic light emitting diode).

Each of the plurality of pixels UP may be configured to implement a black image or a color image. One pixel UP may be a unit pixel. Each of the plurality of pixels UP may include a plurality of subpixels SP. For example, each of the plurality of subpixels SP may be configured to implement one of a plurality of colors (or light) implementing a color image (or color light). For example, each of the plurality of subpixels SP may be configured to include a light emitting device implementing any one of red light, green light, blue light, and white light.

The gate driving circuit 120 may be implemented in the non-display area NDA adjacent to the display area DA to be electrically connected to the pixel part 110. The gate driving circuit 120 may be implemented in a long-side region of the first non-display area NDA1 to be electrically connected to the pixel part 110. For example, the gate driving circuit 120 may be implemented in one or more of a pair of long-side regions of the first non-display area NDA1 to be electrically connected to a plurality of gate lines disposed at the pixel part 110.

The gate driving circuit 120 according to an embodiment of the present disclosure may include one or more of a first gate driving circuit 120A and a second gate driving circuit 120B.

The first gate driving circuit 120A may be implemented in a first long-side region of the first non-display area NDA1 adjacent to a first side (or one side) of the display area DA.

The second gate driving circuit 120B may be implemented in a second long-side region of the first non-display area NDA1 adjacent to a second side (or the other side), which is opposite to the first side (or the one side), of the display area DA.

According to an embodiment of the present disclosure, the first gate driving circuit 120A may be electrically connected to one end of each of a plurality of gate lines, and the second gate driving circuit 120B may be electrically connected to the other end of each of a plurality of gate lines provided in the pixel part 110.

The pad part 130 may be implemented in the non-display area NDA of the substrate 100. The pad part 130 may be implemented at an end region of the second non-display area NDA2 of the non-display area NDA. For example, the pad part 130 may be implemented at an end region of the second non-display area NDA2. For example, the pad part 130 may be implemented at the fourth extension area EA4 of the second non-display area NDA2.

The pad part 130 may receive image data and a timing synchronization signal supplied from a display driving system (or a host driving circuit). The pad part 130 may be electrically connected to a flexible circuit film. The flexible circuit film may be attached on or electrically connected to the pad part 130 by a film attachment process using an anisotropic conductive film. The flexible circuit film may be electrically connected to the display driving system.

The pad part 130 may include a plurality of pads 131 which are disposed at a predetermined interval along the first direction X. The pad part 130 may include a power pad part, a display data pad part, a control signal pad part, a timing signal pad part, and a touch data pad part. For example, each of the power pad part, the display data pad part, the control signal pad part, the timing signal pad part, and the touch data pad part may be configured to include one or more of the plurality of pads 131.

The display driving circuit 140 may be mounted or disposed in the non-display area NDA of the substrate 100. The display driving circuit 140 may be disposed in the second non-display area NDA2 of the non-display area NDA. For example, the display driving circuit 140 may be mounted or disposed in the second extension area EA2 of the second non-display area NDA2. For example, the display driving circuit 140 may be mounted on the substrate 100 by a chip bonding process or a chip on film process.

The display driving circuit 140 may include a plurality of input channels (or bumps) and a plurality of output channels (or bumps).

Each of the plurality of input channels may be electrically connected to the pad part 130 through the plurality of pad connection lines CL. For example, the plurality of pad connection lines CL may be disposed in the third extension area EA3 of the substrate 100 between the display driving circuit 140 and the pad part 130 and may be individually (or a one-to-one relationship) connected between the plurality of input channels and the plurality of pads 131.

Each of the plurality of output channels may be electrically connected to the plurality of data lines Ld and the gate driving circuit 120 through the plurality of routing lines RL. For example, the plurality of routing lines RL may be disposed in the first non-display area NDA1 of the substrate 100 and the bending area BA and the first extension area EA1 of the second non-display area NDA2 of the substrate 100 and may be electrically connected between each of the plurality of data lines Ld and the gate driving circuit 120 and the plurality of output channels. The plurality of pixels UP may be electrically connected to the display driving circuit 140 through the plurality of routing lines RL.

The display driving circuit 140 may generate and output a data signal and a gate control signal, based on the image data and the timing synchronization signal supplied through the pad part 130 from the display driving system. The data signal may be supplied to the data lines of the pixel part 110, and the gate control signal may be supplied to the gate driving circuit 120.

The display driving circuit 140 may generate and output various driving powers (or driving voltages) needed for displaying an image on the pixel part 110, based on an input power (or an input voltage) supplied through the pad part 130 from the display driving system.

The display driving circuit 140 may be configured to include various circuits needed for displaying an image on the pixel part 110. For example, the display driving circuit 140 may include various integrated circuits (ICs) and driving circuits such as a gate control signal generating circuit, a data signal generating circuit, a power generating circuit, and a clock generating circuit.

The light emitting display apparatus (or the display panel) 10 according to an embodiment of the present disclosure may further include a test circuit part disposed under the display driving circuit 140.

The test circuit part may include a plurality of test TFTs electrically connected to the plurality of data lines disposed in the pixel part 110, one or more enable signal pads, and one or more test signal pads. In a test process performed before the display driving circuit 140 is mounted on the substrate 100, each of the plurality of test TFTs may be turned on by an enable signal applied through an enable signal pad and may supply a test signal, applied through a test signal pad, to each of the plurality of data lines.

The light emitting display apparatus (or the display panel) 10 according to an embodiment of the present disclosure may further include an encapsulation part (or encapsulation layer) 150 which covers or surrounds the pixel part 110. The encapsulation part 150 may be configured to protect the pixel part 110. For example, the encapsulation part 150 may be configured to prevent external oxygen or water from penetrating into a display element of the pixel part 110.

The light emitting display apparatus (or the display panel) 10 according to an embodiment of the present disclosure may further include a touch sensing part 160.

The touch sensing part 160 may be disposed or provided on the encapsulation part 150. For example, the touch sensing part 160 may be directly formed or provided at the encapsulation part 150. The touch sensing part 160 may include a touch sensor which senses a user touch. The touch sensing part 160 according to an embodiment of the present disclosure may include a plurality of touch driving electrodes and a plurality of touch sensing electrodes for sensing a touch on the basis of a mutual capacitance type. The touch sensing part 160 according to another embodiment of the present disclosure may include a plurality of touch electrodes (or touch sensing electrodes) for sensing a touch on the basis of a self-capacitance type.

The light emitting display apparatus (or the display panel) 10 according to an embodiment of the present disclosure may include a functional film 170.

The functional film 170 according to an embodiment of the present disclosure may be attached on the sensing part 160. The functional film 170 according to an embodiment of the present disclosure may include a reflection preventing layer (or reflection preventing film) to prevent reflection of external light to improve contrast ratio and outdoor visibility for an image displayed on the display apparatus. For example, the reflection preventing layer may include a polarizing layer or a polarizing film.

The light emitting display apparatus (or light emitting display panel) 10 according to an embodiment of the present disclosure may include an organic layer 180 and a getter layer 190 which are formed at the bending area BA of the substrate 100.

The organic layer 180 may be configured at the bending area BA and a peripheral area of the bending area BA of the substrate 100. For example, the organic layer 180 may be coated at the bending area BA and the peripheral area of the bending area BA of the substrate 100. The organic layer 180 may include a plurality of organic layers 180. A third organic layer 185 which is configured on an uppermost part of the plurality of organic layers 180 may be formed to cover the routing lines RL disposed at the second non-display area NDA2 of the substrate 100. The third organic layer 185 of the plurality of organic layers 180 may configured to protect the routing lines RL at the bending area BA from an external impact.

The getter layer 190 may be configured at the bending area BA of the substrate 100. The getter layer 190 may be spaced apart from the display area DA. The getter layer 190 may be spaced apart from the display area DA. The getter layer 190 may be configured between the first non-display area NDA1 and the extension area EA. One end of the getter layer 190 may be spaced apart from the first non-display area NDA. The other end of the getter layer 190 may be spaced apart from the extension area EA. The getter layer 190 may not overlap the first non-display area NDA1. The getter layer 190 may not overlap the extension area EA.

The getter layer 190 may include a first getter pattern and a second getter pattern having a line shape. The first getter pattern and the second getter pattern may be disposed in parallel with each other. The first getter pattern and the second getter pattern may contact each other. The getter layer 190 may be simultaneously configured by using a same process as the touch sensing part 160. The first getter pattern may include a same material as a touch buffer layer of the touch sensing part 160 and may be configured by using a same process as the touch buffer layer. The second getter pattern may include a same material as a touch sensor layer of the touch sensing part 160 and may be configured by using a same process as the touch sensor layer. The second getter pattern may include a same material as the plurality of touch electrodes of the touch sensor layer and may be configured by using a same process as the plurality of touch electrodes. Accordingly, the first getter pattern and the second getter pattern may be made of different materials. For example, the getter layer 190 may be a moisture absorption layer, a moisture permeation prevention layer, or a crack prevention layer.

According to an embodiment of the present disclosure, since the light emitting display apparatus 10 includes the getter layer 190 disposed at the bending area BA, hydrogen or moisture may be prevented from penetrating into the display panel.

According to an embodiment of the present disclosure, the light emitting display apparatus 10 may prevent hydrogen or moisture from penetrating into the display panel, thereby preventing corrosion of the thin film transistor and the metal lines (or wiring). Accordingly, reliability of the light emitting display apparatus may be improved.

According to an embodiment of the present disclosure, the light emitting display apparatus 10 may include a getter layer configured at the bending area BA, thereby preventing deterioration and characteristics of a device due to corrosion of the thin film transistor and the metal lines (or wirings). Accordingly, the lifespan of the light emitting display apparatus 10 may be improved, and low-power driving of the light emitting display apparatus 10 may be possible.

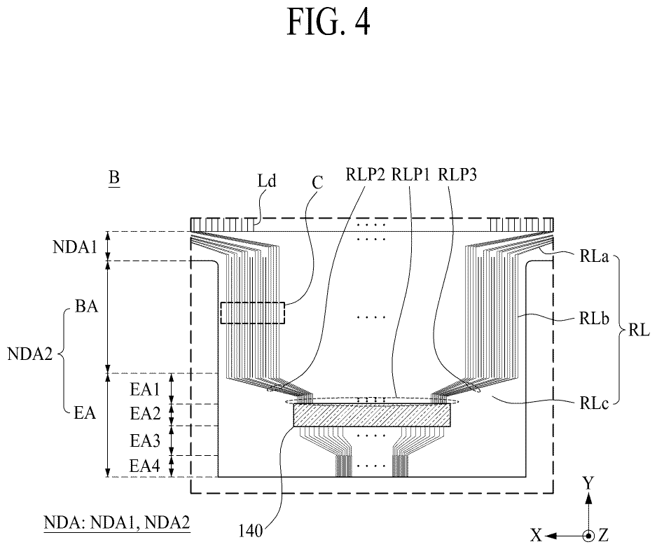

The organic layer 180 and the getter layer 190 of the light emitting display apparatus 10 will be described in more detail below with reference to FIGS. 4 to 6.

The light emitting display apparatus (or the display panel) 10 according to an embodiment of the present disclosure may further include a supporting member 200.

The supporting member 200 may be configured to support the other portion, except the bending region BA, of the substrate 100. The supporting member 200 may maintain the other portion, except the bending region BA, of the substrate 100 in a flat state.

The supporting member 200 according to an embodiment of the present disclosure may include a first supporting plate 210, a second supporting plate 220, and a coupling member 230.

The first supporting plate 210 may be configured to support a rear surface (or a backside surface) of the substrate 100 overlapping with the display area DA. For example, the first supporting plate 210 may be coupled to or attached on the rear surface (or the backside surface) of the substrate 100 overlapping with the display area DA and the first non-display area NDA1.

The second supporting plate 220 may be configured to support a rear surface (or a backside surface) of the substrate 100 overlapping with the extension region EA of the non-display area NDA. For example, the second supporting plate 220 may be coupled to or attached on the rear surface (or the backside surface) overlapping with the other extension region EA, except the bending region BA, of the second non-display area NDA2 of the non-display area NDA.

The bending region BA of the substrate 100 may be located between the first supporting plate 210 and the second supporting plate 220. The bending area BA of the substrate 100 may be bent to surround one lateral surface of the first supporting plate 210 facing the second supporting plate 220. The extension region EA of the substrate 100 may be disposed on the rear surface (or the backside surface) of the substrate 100 overlapping with the display area DA of the substrate 100. Accordingly, the light emitting display apparatus according to an embodiment of the present disclosure may decrease in bezel width which occurs due to the second non-display area NDA2 of the non-display area NDA, and thus, may have a thin bezel width.

The coupling member 230 may be connected or coupled between the first supporting plate 210 and the second supporting plate 220. The coupling member 230 may couple or fix the second supporting plate 220 to the rear surface (or the backside surface) of the first supporting plate 210, and thus, may bend the bending region BA of the substrate 100 at a certain curvature (or a curvature radius) and may maintain a bending state and a bending shape of the bending region BA of the substrate 100.

According to an embodiment of the present disclosure, a first surface of the coupling member 230 may be attached on a rear periphery portion of the first supporting plate 210 by a first attachment member 231. The second surface of the coupling member 230 may be attached on a rear surface of the second supporting plate 220 by a second attachment member 232.

The supporting member 200 according to an embodiment of the present disclosure may further include a third supporting plate 250.

The third supporting plate 250 may be coupled to or attached on a rear surface of the first supporting plate 210. For example, the third supporting plate 250 may be coupled to or attached on the rear surface of the first supporting plate 210 by an adhesive member 260.

The third supporting plate 250 according to an embodiment of the present disclosure may be coupled to or attached on an entire rear surface of the first supporting plate 210. Accordingly, the coupling member 230 or the first surface of the coupling member 230 may be attached on a rear periphery portion of the third supporting plate 250 by the first attachment member 231.

The third supporting plate 250 may include a metal material. For example, the third supporting plate 250 may include a metal layer. For example, the third supporting third supporting plate 250 may function as a noise prevention layer which prevents static electricity or frequency noise, occurring in the display driving system connected to the pad part 130, from penetrating into the pixel part 110.

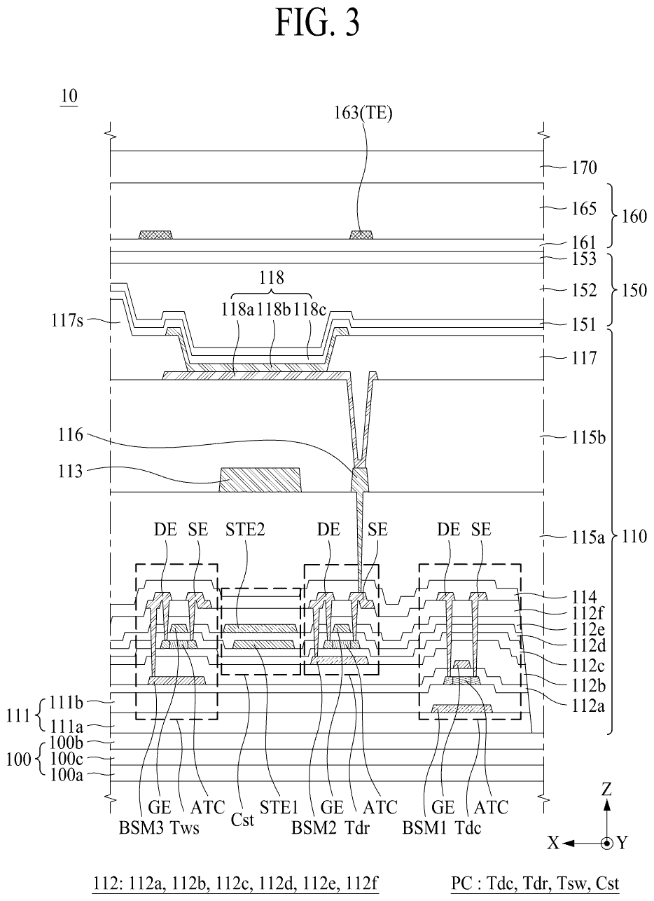

FIG. 3 is an enlarged view illustrating region ‘A’ illustrated in FIG. 2. FIG. 3 is a cross-sectional view schematically illustrating one subpixel illustrated in FIGS. 1 and 2.

Referring to FIGS. 1 to 3, the light emitting display apparatus 10 according to an embodiment of the present disclosure may include a substrate 100, a pixel part 110, an encapsulation part 150, and a touch part 160.

The substrate 100 may include one or more plastic material layer. For example, the substrate 100 may include a first base substrate 100a and a second base substrate 100b stacked on the first base substrate 100a. Each of the first and second base substrates 100a and 100b may include a plastic material such as polyimide or the like.

The substrate 100 may include a middle layer 100c which is disposed or interposed between the first base substrate 100a and the second base substrate 100b. The middle layer 100c may be configured to prevent the penetration of water through the substrate 100. The middle layer 100c may be configured to electrically insulate the substrate 100. For example, the middle layer 100c may include an electrical insulating material. For example, the middle layer 100c may include an inorganic material.

The pixel part 110 may include a buffer layer 111, a pixel circuit PC, an overcoat layer 115, and a light emitting device layer 118.

The buffer layer 111 may be disposed on the substrate 100. The buffer layer 111 may include a first buffer layer 111a and a second buffer layer 111b.

The first buffer layer 111a may prevent a material of the substrate 100 from being diffused to a transistor in performing a high temperature process in a manufacturing process of a TFT, or may prevent external water or moisture from penetrating into the light emitting device layer 118. Optionally, the first buffer layer 111a may be omitted based on the kind and material of the substrate 100.

The second buffer layer 111b may be disposed over the first buffer layer 111b. The second buffer layer 111b may be formed between a first light blocking layer BSM1 and an active layer ACT of a driving circuit thin film transistor Tdc. The first light blocking layer BSM1 may be configured to prevent changes in a threshold voltage Vth of the thin film transistor caused by external light incident from an outside of the display panel.

The pixel circuit PC may include a driving circuit thin film transistor Tdc which is provided at a pixel region on the substrate 100 or the buffer layer 111.

The driving circuit thin film transistor Tdc may include an active layer ACT, a gate electrode GE, a source electrode SE, and a drain electrode DE.

In the driving circuit thin film transistor Tdc, the active layer ACT may be disposed on the substrate 100 or the buffer layer 111. For example, the active layer ACT may include a semiconductor material based on metal oxide such as indium-gallium-zinc-oxide (IGZO), but is not limited thereto and may include a semiconductor material based on silicon such as amorphous silicon or polycrystalline silicon. For example, a semiconductor material may be deposited on the buffer layer 111b, and the active layer ACT may be formed in a pattern shape by an annealing process for stabilization and a patterning process on the semiconductor material.

The active layer ACT may include a source region, a drain region, and a channel region between the source region and the drain region. The active layer ACT may be covered by a first insulation layer 112a.

The first insulation layer 112 may be formed in an island shape on only the channel region of the active layer ACT, or may be formed to cover an entire front surface of the buffer layer 111 or the substrate 100 including the active layer ACT.

In the driving circuit thin film transistor Tdc, the gate electrode GE may be disposed on the first insulation layer 112a to overlap with the channel region of the active layer ACT. The gate electrode GE may be formed of a gate metal material. For example, the gate electrode GE may include a single layer or a multilayer made of a single metal material including molybdenum (Mo), copper (Cu), titanium (Ti), aluminum (Al), chromium (Cr), gold (Au), nickel (Ni), or neodymium (Nd), or an alloy thereof. The gate electrode GE may be formed together with a gate line.

In the driving circuit thin film transistor Tdc, the gate electrode GE may be covered by a second insulation layer 112b. The second insulation layer 112b may be formed on the first insulation layer 112a to cover the gate electrode GE. The second insulation layer 112b may be configured with a single layer of an inorganic material including nitride silicon (SiNx) or oxide silicon (SiOx), or a multilayer thereof, but is not limited thereto and may include an organic material.

In the driving circuit thin film transistor Tdc, the source electrode SE may be disposed on a six insulation layer 112f to be electrically connected to the source region of the active layer ACT. The second to sixth insulation layers 112b to 112f may be sequentially stacked between the gate electrode GE and the source electrode SE. The source electrode SE may be electrically connected to the source region of the active layer ACT through a contact hole which is formed at the first to sixth insulation layers 112a to 112e overlapping the source region of the active layer ACT. The first to sixth insulation layers 112a to 112f may be configured with a single layer of an inorganic material including nitride silicon (SiNx) or oxide silicon (SiOx), or a multilayer thereof.

In the driving circuit thin film transistor Tdc, the drain electrode DE may be disposed on the six insulation layer 112f to be electrically connected to the drain region of the active layer ACT. The drain electrode DE may be electrically connected to the drain region of the active layer ACT through a contact hole which is formed at the first to sixth insulation layers 112a to 112f overlapping with the drain region of the active layer ACT.

The source electrode SE and the drain electrode DE may be formed of a source/drain metal material. For example, the source electrode SE and the drain electrode DE may be configured with a conductive material which is a same as or different from that of the gate electrode GE. The source electrode SE and the drain electrode DE may be together with a data line.

The pixel circuit PC may include a driving thin film transistor Tdr which is disposed at the pixel region on the substrate 100 or the buffer layer 111.

The driving thin film transistor Tdr may include an active layer ACT, a gate electrode GE, a source electrode SE, and a drain electrode DE.

In the driving thin film transistor Tdr, the active layer ACT may be disposed on the substrate 100 or the third insulation layer 112c. For example, the active layer ACT has a same configuration and include a same material as the active layer ACT of the driving circuit thin film transistor Tdc. The active layer ACT may be covered by the fourth insulation layer 112d.

In the driving thin film transistor Tdr, the gate electrode GE may be disposed on the fourth insulation layer 112d to overlap the channel region of the active layer ACT. For example, the gate electrode GE may have a same configuration and include a same material as the gate electrode GE of the driving circuit thin film transistor Tdc. The gate electrode GE may be covered by the fifth insulation layer 112e.

In the driving thin film transistor Tdr, the source electrode SE may be disposed on the sixth insulation layer 112f to be electrically connected to the source region of the active layer ACT. The source electrode SE may be electrically connected to the source region of the active layer ACT through a contact hole which is formed at the fourth to sixth insulation layers 112d to 112f overlapping the source region of the active layer ACT.

In the driving thin film transistor Tdr, the drain electrode DE may be disposed on the sixth insulation layer 112f to be electrically connected to the drain region of the active layer ACT. The drain electrode DE may be electrically connected to the drain region of the active layer ACT through a contact hole which is formed at the fourth to sixth insulation layers 112d to 112f overlapping the drain region of the active layer ACT.

The driving thin film transistor Tdr may further include a second light blocking layer BSM2 under the active layer ACT. The second light blocking layer BSM2 may be configured to prevent changes in a threshold voltage Vth of the driving thin film transistor Tdr caused by external light incident from an outside of the display panel.

The pixel circuit PC may further include at least one switching thin film transistor and at least one capacitor, which is disposed at the pixel region. The at least one switching thin film transistor and the at least one capacitor may be together with the driving thin film transistor TFT, only different configurations will be described below.

The switching thin film transistor Tsw may include an active layer ACT, a gate electrode GE, a source electrode SE, and a drain electrode DE. The active layer ACT, the gate electrode GE, the source electrode SE, and the drain electrode DE of the switching thin film transistor Tsw may be configured at a same layer as the active layer ACT, gate electrode GE, source electrode SE, and drain electrode DE of the driving thin film transistor Tdr, and may have a same structure of the driving thin film transistor Tdr.

The switching thin film transistor Tsw may further include a third light blocking layer BSM3 under the active layer ACT. the second and third insulation layers 112b and 112c may be configured between the active layer ACT and the third light blocking layer BSM3 of the switching thin film transistor Tsw. The third light blocking layer BSM3 may be electrically connected to the drain electrode DE of the switching thin film transistor Tsw. The third light blocking layer BSM3 may be configured at a same layer as the gate electrode GE of the driving circuit thin film transistor Tdc, and may be configured by using a same process as the gate electrode GE of the driving circuit thin film transistor Tdc. The third light blocking layer BSM3 may be configured to prevent changes in a threshold voltage Vth of the switching thin film transistor Tsw caused by external light incident from an outside of the display panel.

The at least one capacitor Cst may be configured between the switching thin film transistor Tsw and the driving thin film transistor Tdr.

The capacitor Cst may store a data voltage applied through the data line for a predetermined period of time, and then provide the stored data voltage to the light emitting device layer 118. The capacitor Cst may include two electrodes corresponding to each other and a dielectric material interposed therebetween. The at least one capacitor Cst may include a first storage electrode STE1 and a second storage electrode STE2. The fifth insulation layer 112e may be disposed between the first storage electrode STE1 and the second storage electrode STE2.

The pixel circuit PC may be covered by a passivation layer 114. The passivation layer 114 may be configured with a single layer of an inorganic material including nitride silicon (SiNx) or oxide silicon (SiOx), or a multilayer thereof.

The overcoat layer 115 may be disposed to cover the pixel circuit PC or the passivation layer 114. For example, the overcoat layer 115 may be implemented to planarize an upper portion of the passivation layer 114 or the pixel circuit PC and protect the pixel circuit PC. For example, the overcoat layer 115 may be configured with an organic material. For example, the overcoat layer 115 may be formed of an organic material including acrylic resin, epoxy resin, phenol resin, polyamide resin, polyimide resin.

The overcoat layer 115 may include a first planarization layer 115a and a second planarization layer 115b formed on the first planarization layer 115a. The first planarization layer 115a and the second planarization layer 115b may have the same thickness, or may have different thicknesses.

The light emitting device layer 118 may include a first electrode 118a, a light emitting device 118b, and a second electrode 118c.

The first electrode 118a may be disposed in a pattern shape on the overcoat layer 115. The first electrode 118a may be electrically connected to the source electrode SE of the driving thin film transistor TFT through an electrode contact hole which is formed at the overcoat layer 115.

The light emitting device 118b may be disposed on the first electrode 118a. The light emitting device 118b may include one or more emission structure which are stacked on the first electrode 118a in the order or reverse order of a hole layer, a light emitting layer, and an electron layer. For example, the light emitting device 118b may be implemented to generate color light corresponding to a corresponding subpixel. For example, the light emitting layer of each of the plurality of emission structures may generate one or more of blue light, green light, and red light or mixed light thereof.

The second electrode 118c may be disposed on the light emitting device 118b. The second electrode 118c may be disposed on the light emitting device 118b to face the first electrode 118a with the light emitting device 118b therebetween.

The light emitting display apparatus 10 according to an embodiment of the present disclosure may further include a bank 117.

The bank 117 may be disposed to define an opening portion (or an emission region) of a subpixel SP and cover a periphery portion of the first electrode 118a. For example, the bank 117 may be disposed on the overcoat layer 115 to cover only a periphery portion, except a center portion, of the first electrode 118a. For example, the bank 117 may include an organic material or an inorganic material, or may include a light absorbing material including a black pigment.

A bank projection 117s may be disposed on the bank 117. The bank projection 117s may protrude from the bank 117 and may be disposed on the bank 117 with a material different from that of the bank 117. For example, the bank projection 117s may be configured to support a mask for formation of the light emitting device 118b. For example, the bank projection 117s may be a spacer.

The light emitting device 118b may be disposed in only the opening portion of each subpixel SP provided by the bank 117, or may be disposed on the bank 117 and the opening portion of each subpixel SP.

The light emitting display apparatus according to an embodiment of the present disclosure may further include a connection electrode (or a middle electrode) 116 disposed in the overcoat layer 115, to prevent the occurrence of a pattern defect (or a contact defect) of the first electrode 118a caused by a distance between the first electrode 118a and the source electrode SE of the driving thin film transistor TFT.

The connection electrode 116 may be configured to be electrically connected to the source electrode SE or the drain electrode DE of the driving thin film transistor TFT and the first electrode 118a. For example, the connection electrode 116 may be disposed on the first planarization layer 115a overlapping with the source electrode SE of the driving thin film transistor TFT and may be covered by the second planarization layer 115b. The first electrode 118a may be stably connected to the source electrode SE of the driving thin film transistor TFT through the connection electrode 116.

According to an embodiment of the present disclosure, an additional auxiliary line 113 for driving of the pixel circuit PC and/or emission of light from the light emitting device 118b may be disposed between the first planarization layer 115a and the second planarization layer 115b. For example, the auxiliary line 113 may be formed of a same material in a same process as the connection electrode 116, but embodiments of the present disclosure are not limited thereto.

The encapsulation part 150 may be configured to cover or surround the pixel part 110. For example, the encapsulation part 150 may be disposed on the light emitting device layer 118 and may cover or surround the light emitting device layer 118.

The encapsulation part 150 may include at least one or more encapsulation layers. For example, the encapsulation part (or an encapsulation layer) 150 may include one or more inorganic encapsulation layers and one or more organic encapsulation layers on the light emitting device layer 118. For example, the encapsulation part (or an encapsulation layer) 150 may include a first encapsulation layer 151, a second encapsulation layer 152, and a third encapsulation layer 153.

The first encapsulation layer 151 may be disposed on the second electrode 118c. The second encapsulation layer 152 may be disposed on the second electrode 118c or the first encapsulation layer 151. The third encapsulation layer 153 may be disposed on the second electrode 118c or the second encapsulation layer 152.

The light emitting display apparatus 10 or the display panel according to an embodiment of the present disclosure may further include a touch sensing part 160 which is disposed on the display area DA of the substrate 100.

The touch sensing part 160 may be disposed on the encapsulation part 150. For example, the touch sensing part 160 may be disposed on the third encapsulation layer 153 of the encapsulation part 150.

The touch sensing part 160 may include a touch buffer layer 161, a touch sensor layer 163, and a touch protection layer 165.

The touch buffer layer 161 may be disposed on the third encapsulation layer 153 of the encapsulation part 150. For example, the touch buffer layer 161 may be formed of an inorganic material including nitride silicon (SiNx) or oxide silicon (SiOx), but the embodiments of the present disclosure are not limited thereto.

The touch sensor layer 163 may include a plurality of touch electrodes TE disposed on the touch buffer layer 161. The plurality of touch electrodes TE may be made of transparent metal or opaque metal. For example, the plurality of touch electrodes TE may include a plurality of touch sensing electrodes or a plurality of touch driving electrodes.

The touch protection layer 165 may be disposed on the touch buffer layer 161 to cover the touch sensor layer 163. The touch protection layer 165 may be configured to planarize an upper portion of the touch sensing part 160 and protect the touch sensing part 160. For example, the touch protection layer 169 may be formed of an organic material.

The light emitting display apparatus 10 or the display panel according to an embodiment of the present disclosure may further include a functional film 170 which is disposed on the touch sensing part 160.

The functional film 170 may include a reflection preventing layer (or reflection preventing film) which is attached on the touch sensing part 160. For example, the reflection preventing layer may include a circular polarizing layer (or circular polarizing film), but the embodiments of the present disclosure are not limited thereto.

FIG. 4 is an enlarged view illustrating region ‘B’ illustrated in FIG. 1. FIG. 4 is diagram for describing routing lines of the light emitting display apparatus according to an embodiment of the present disclosure.

Referring to FIGS. 1 and 4, the light emitting display apparatus 10 according to an embodiment of the present disclosure may include a plurality of routing line portions RLP1, RLP2, and RLP3 to electrically connect each of the pixel part 110 and the gate driving circuit 120 to the display driving circuit 140. For example, the light emitting display apparatus 10 according to an embodiment of the present invention may include first to third routing line portions RLP1, RLP2, and RLP3.

Each of the first to third routing line portions RLP1, RLP2, and RLP3 may be formed or disposed at an area between the display area DA and the display driving circuit 140 of the non-display area NDA of the substrate 100. For example, each of the first to third routing line portions RLP1, RLP2, and RLP3 may be disposed at one side area of the first non-display area NDA1, the bending area BA, and the first extension area EA1 of the non-display area NDA of the substrate 100.

Each of the first to third routing line portions RLP1, RLP2, and RLP3 may include a plurality of routing lines RL.

Some of the plurality of routing lines RL of the first routing line unit RLP1 may be electrically connected to each of end portions of each of the plurality of data lines Ld in one side area of the first non-display area NDA1 and each of a plurality of data output channels disposed at the display driving circuit 140 in the second extension area EA2 of the second non-display area NDA2. The remaining routing lines RL of the first routing line portion RLP may be electrically connected to each of the plurality of touch electrodes.

The display driving circuit 140 may supply a data signal to each of a plurality of data lines Ld which are disposed at the display area DA of the substrate 100 through the first routing line portion RLP1. The display driving circuit 140 may supply a touch driving signal to each of the touch electrodes which are disposed at the display area DA of the substrate 100 through the first routing line portion RLP1 or may detect a user touch through the first routing line portion RLP1.

The plurality of routing lines RL of the second routing line portion RLP2 may be electrically connected to each of the plurality of first gate output channels of the plurality of output channels which are disposed at the first gate driving circuit 120A and the display driving circuit 140.

The plurality of routing lines RL of the third routing line portion RLP3 may be electrically connected to each of a plurality of second gate output channels of a plurality of output channels which are disposed at the second gate driving circuit 120B and the display driving circuit 140.

The plurality of third routing lines may be configured in a symmetrical (or a horizontal symmetrical) structure with the plurality of second routing lines centered on first routing line portion RLP1.

The routing line RL included in each of the first to third routing line portions RLP1, RLP2, and RLP3 may include a first line portion RLa, a second line portion RLb, and a third line portion RLc.

The first line portion RLa may be disposed at one side area of the first non-display area NDA1 of the substrate 100. For example, the first line portion RLa may be disposed to have a non-linear shape on the substrate 100 between the display area DA and the bending area BA of the substrate 100. The first end portion (or a start portion) of the first line portion RLa may be electrically connected to the data line, the touch connection line, or the gate driving circuit 120. The first line portion RLa may have a non-linear shape, an oblique shape, or a diagonal shape.

The second line portion RLb may be disposed at the bending area BA of the substrate 100. For example, the second line portion RLb may be disposed to have a straight line shape on the bending area BA of the substrate 100.

The third line portion RLc may be disposed between the bending area BA of the substrate 100 and the display driving circuit 140. The third line portion RLc may be disposed on the first extension area EA1 of the substrate 100 to have a non-linear shape.

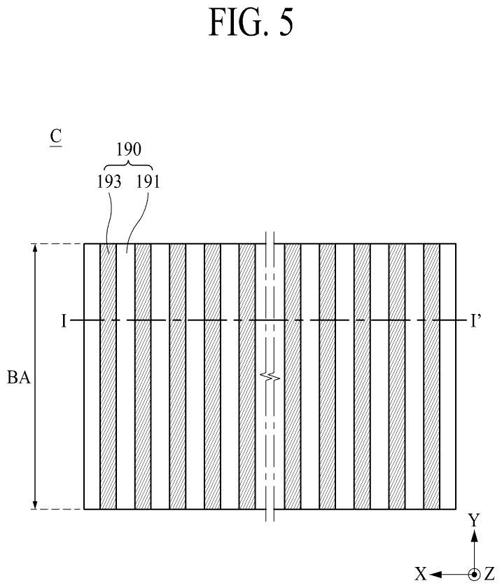

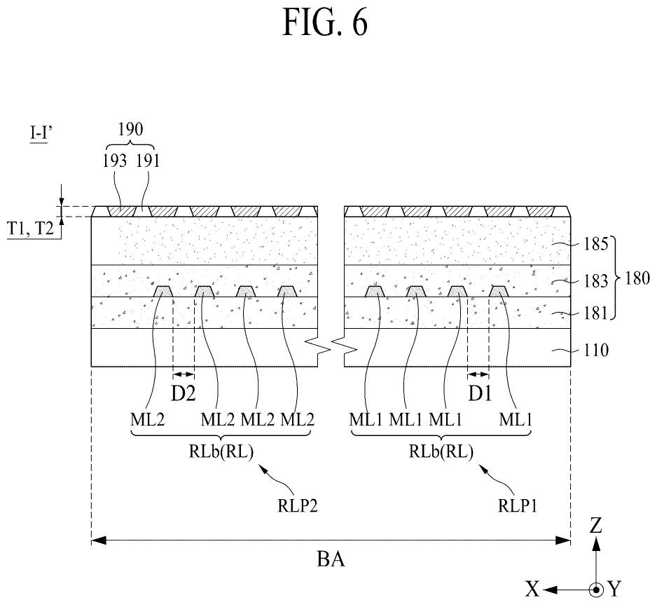

FIG. 5 is an enlarged view illustrating an example of region ‘C’ illustrated in FIG. 4. FIG. 6 is a cross-sectional view taken along line I-I′ shown in FIG. 5. FIGS. 5 and 6 are diagram illustrating a bending area and a getter layer according to an embodiment of the present disclosure described above with reference to FIGS. 1 to 4.

Referring to FIGS. 3, 5, and 6, the bending area BA of the light emitting display apparatus according to an embodiment of the present disclosure may include an organic layer 180, routing lines RL, and a getter layer 190.

The organic layer 180 may include first to third organic layers 181, 183, and 185. The first to third organic layers 181, 183, and 185 may be sequentially stacked at the bending area BA on the substrate 100.

The first organic layer 181 may be disposed at the bending area BA on the substrate 100. The first organic layer 181 may be in direct contact with a front surface (or an upper surface) 100f of the substrate 100. For example, each of the buffer layer 111, the insulation layer 112, and the passivation layer 114 formed of an inorganic material disposed in the bending area BA of the substrate 100 may be removed before a formation process of the first organic layer 181. For example, the inorganic material layers 111, 112, and 114 disposed in the bending area BA of the substrate 100 are vulnerable to bending stress when formed on a front surface of the substrate 100, and thus, may be easily damaged by bending of the substrate 100. For example, the routing lines RL configured at the bending area BA may be damaged due to the damage of the inorganic material layers 111, 112, and 114. For example, hydrogen or moisture may penetrate into the damaged areas of the inorganic material layers 111, 112, and 114, and thus, corrosion may occur in the routing lines RL configured at the bending area BA. Accordingly, the first organic layer 181 may be disposed at the bending area BA of the substrate 100 from which the inorganic material layers 111, 112, and 113 are removed, and may be in direct contact with the front surface 100f of the substrate 100.

The first organic layer 181 may include a same material as the first planarization layer 115a and may be configured using a same process as the first planarization layer 115a. For example, the first organic layer 181 may be formed of an organic material including acrylic resin, epoxy resin, phenol resin, polyamide resin, polyimide resin.

The second organic layer 183 may be disposed at the bending area BA on the substrate 100. The second organic layer 183 may be disposed on the first organic layer 181. The second organic layer 181 may cover the plurality of routing lines RL in the bending area BA, and may be in direct contact with a front surface (or an upper surface) of the first organic layer 181. The second organic layer 183 may include a same material as the second planarization layer 115b and may be formed using a same process as the second planarization layer 115b. For example, the second organic layer 181 may be formed of an organic material.

The third organic layer 185 may be disposed at the bending area BA on the substrate 100. The third organic layer 185 may be disposed on the second organic layer 183. The third organic layer 185 may be in direct contact with a front surface (or an upper surface) of the second organic layer 183. The third organic layer 185 may include a same material as or different from the first organic layer 181 and the second organic layer 183. For example, the third organic layer 185 may include a same material as the bank 117 and may be configured using a same process as the bank 117. As another example, the bank layer 117 may be additionally formed at the bending area BA. The third organic layer 185 may be a bank layer additionally formed at the bending area BA.

The third organic layer 185 may protect the routing lines RL in the bending area BA from an external impact. For example, when the bending area BA of the substrate 100 is bent in a curved shape, the third organic layer 185 may allow routing lines to be located in a neutral plane of the bending area BA. For example, when the bending area BA of the substrate 100 is bent in a curved shape, a neutral surface having a tensile force and a compressive force of 0 (zero) exists between the substrate 100 and the third organic layer 180. Accordingly, the third organic layer 180 may include a material having a higher modulus of elasticity (or Young's modulus) than the substrate 100 so that the routing lines may be located in the neutral plane of the bending area BA. Accordingly, since the routing lines in the bending area BA are located in the neutral plane between the third organic layer 180 and the substrate 100, when the bending area BA of the substrate 100 is bent in a curved shape, the routing lines receive zero bending stress, and thus may be bent without being damaged by bending stress.

In the light emitting display apparatus according to an embodiment of the present disclosure, the routing lines RL of the first routing line portion RLP1 may be disposed on the first organic layer 181. The routing lines RL of the first routing line portion RLP1 may be disposed between the first organic layer 181 and the second organic layer 183. The first routing line portion RLP1 may be first fine lines ML1 configured at the second line portion RLb of the routing lines RL. The first fine lines ML1 may be disposed at the bending area BA of the substrate 100. The first fine lines ML1 may be disposed in parallel to have a first interval D1 along the first direction X.

The routing lines RL of the second routing line portion RLP2 may be disposed at the first organic layer 181. The routing lines RL of the second routing line portion RLP2 may be disposed between the first organic layer 181 and the second organic layer 183. The second routing line portion RLP2 may be a second fine lines ML2 which are configured at the second line portion RLb of the routing lines RL. The second fine lines ML2 may be disposed at the bending area BA of the substrate 100. The second fine lines ML2 may be disposed in parallel to have a second interval D2 along the first direction X. The first interval D1 and the second interval D2 may be a same, but are not limited thereto. For example, each of the first fine lines ML1 and the second fine lines ML2 may be formed of a same material in a same process as the source electrode SE (or the drain electrode DE).

The getter layer 190 may be configured at the bending area BA on the substrate 100. The getter layer 190 may be configured on the organic layer 180. The getter layer 190 may be formed on the third organic layer 185. The getter layer 190 may be formed on a bank layer additionally formed at the bending area BA or the third organic layer 185.

The getter layer 190 may be spaced apart from the display area DA on the substrate 100. The getter layer 190 may be configured at the bending area BA between the first non-display area NDA1 and the extension area EA. One side end of the getter layer 190 may be spaced apart from the first non-display area NDA. The other side end of the getter layer 190 may be spaced apart from the extension area EA. The getter layer 190 may not overlap the display area DA, the first non-display area NDA1, and the extension area EA. The getter layer 190 may be configured at the bending area BA excluding the display area DA, the first non-display area NDA1, and the extension area EA.

According to an embodiment of the present disclosure, since the getter layer 190 is spaced apart from the display area DA on the substrate 100, hydrogen and moisture may be prevented from penetrating from the upper surface of the organic layer 180 without affecting the display area DA. For example, the getter layer 190 may be spaced apart from the display area DA and may be configured to cover an entire upper surface of the bending area BA or an entire upper surface of the third organic layer 185. Accordingly, the getter layer 190 may prevent hydrogen and moisture from penetrating from the upper surface of the bending area BA or the third organic layer 185.

The getter layer 190 may include a plurality of first getter patterns 191 and a plurality of second getter patterns 193. Each of the plurality of first getter patterns 191 and the plurality of second getter patterns 193 may be disposed in parallel along the first direction X at the bending area BA on the substrate 100. A side surface of the first getter pattern 191 and a side surface of the second getter pattern 193 adjacent to each other may be in contact with each other. Accordingly, the first getter pattern 191 and the second getter pattern 193 may be configured to cover the entire upper surface of the third organic layer 185.

Each of the plurality of first getter patterns 191 may be disposed in parallel along the first direction X at the bending area BA on the substrate 100. Each of the plurality of first getter patterns 191 may have a linear shape extending along the second direction Y. Each of the plurality of first getter patterns 191 may be disposed between the plurality of second getter patterns 193. For example, each of the plurality of first getter patterns 191 may be disposed between two adjacent second getter patterns 193. Each of the plurality of first getter patterns 191 may be in contact with an adjacent second getter pattern 193. The side surfaces of each of the plurality of first getter patterns 191 may be in contact with side surfaces of adjacent second getter patterns 193.

According to an embodiment of the present disclosure, the first getter pattern 191 may include a same material as the touch buffer layer 161 configured in the display area DA, and may be formed through a same process as the touch buffer layer 161. For example, the first getter pattern 191 may be composed of a single layer of an inorganic material including silicon nitride (SiNx) or silicon oxide (SiOx), or multiple layers thereof. According to an embodiment of the present disclosure, the first getter pattern 191 is not configured as a single layer, has the plurality of first getter patterns 191 and is disposed in parallel with each other, and thus damage or crack due to stress due to bending may be prevented as compared with that configured as a single layer.

Each of the plurality of second getter patterns 193 may be disposed in parallel along the first direction X in the bending area BA on the substrate 100. Each of the plurality of second getter patterns 193 may have a line shape extending along the second direction Y. Each of the plurality of second getter patterns 193 may be disposed between the plurality of first getter patterns 191. Each of the plurality of second getter patterns 193 may be in contact with an adjacent first getter pattern 191. The side surfaces of each of the plurality of second getter patterns 192 may be in contact with the side surfaces of adjacent first getter patterns 191. For example, the plurality of second getter patterns 193 may be inserted between the plurality of first getter patterns 191. For example, the plurality of second getter patterns 193 may include a same material as the touch electrode TE of the touch sensor layer 163 described above with reference to FIG. 3, and may be formed through the same process as the touch electrode TE. For example, the plurality of second getter patterns 193 may include a metal material. For example, each of the plurality of second getter patterns 193 may include a meta material. For example, each of the plurality of second getter patterns 193 may include titanium (Ti). For example, the titanium has strong corrosion resistance and excellent chemical resistance to alkali and acidic solutions. In addition, titanium oxide film formed on a surface of the titanium exhibits excellent corrosion resistance and may act as an effective barrier to block hydrogen permeation by capturing hydrogen, which impacts the performance of thin film transistor.

The embodiment of the present disclosure may absorb hydrogen and moisture penetrating into an upper portion of the organic layer 180 disposed in the bending area BA by including a metal material containing titanium as the second getter pattern 193.

According to an embodiment of the present disclosure, each of the plurality of first getter patterns 191 and the plurality of second getter patterns 193 may be spaced apart from the display area DA. Each of the plurality of first getter patterns 191 and the plurality of second getter patterns 193 may not be disposed at the first non-display area NDA1. Each of the plurality of first getter patterns 191 and the plurality of second getter patterns 193 may be provided between the first non-display area NDA1 and the extension area EA. Ends of the plurality of first getter patterns 191 and ends of the plurality of second getter patterns 193 may be spaced apart from the extension area EA, respectively.

For example, the organic layers 180 disposed at the bending area BA which is connected to the display area DA of the substrate 100 may cause less damage such as a crack than the insulating layer 112 including an inorganic material, but hydrogen and moisture may penetrate from the upper surface and the side surface of the organic layer 180. Since the upper surface of the organic layer 180 has a large area, there is a high possibility that hydrogen and moisture may penetrate into the upper surface of the organic layer 180, and when hydrogen and moisture penetrate into the upper surface of the organic layer 180, corrosion or the like may occur due to the penetration of hydrogen and moisture into the thin film transistor and the metal lines (or metal wires) disposed at the display area DA.

According to an embodiment of the present disclosure, by configuring the getter layer 190 including the first getter pattern 191 and the second getter pattern 193, hydrogen and moisture may be prevented from penetrating from the bending area BA, thereby preventing corrosion of the thin film transistor and the metal lines (or metal wires) configured inside the display panel.

Accordingly, deterioration and defects of the light emitting display apparatus according to an embodiment of the present disclosure may be prevented, and reliability may be improved.

According to an embodiment of the present disclosure, the plurality of first getter patterns 191 and the plurality of second getter patterns 193 may have a same thickness. For example, when the plurality of first getter patterns 191 and the plurality of second getter patterns 193 have different thicknesses, hydrogen and moisture may penetrate from the side surfaces of the plurality of first getter patterns 191 and the plurality of second getter patterns 193 adjacent to each other. Accordingly, the plurality of first getter patterns 191 and the plurality of second getter patterns 193 may be set to have the same thickness, thereby minimizing the penetration of hydrogen and moisture generated at the interface of the plurality of first getter patterns 191 and the plurality of second getter patterns 193.

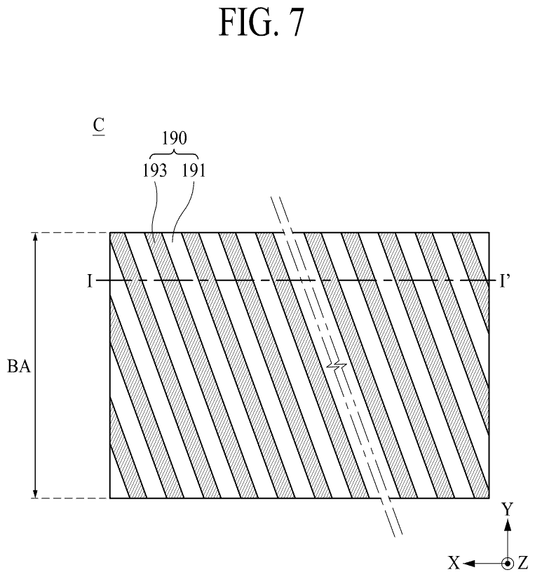

FIG. 7 is an enlarged view illustrating another example of region ‘C’ illustrated in FIG. 4. FIG. 7 illustrates an embodiment implemented by modifying shapes of the first getter pattern and the second getter pattern in the light emitting display apparatus described above with reference to FIGS. 1 to 6. In the following description, therefore, repetitive descriptions of the other elements except the first getter pattern and the second getter pattern, and relevant elements, are omitted or will be briefly given below.

Referring to FIG. 7, each of the first and second getter patterns 191 and 193 according to another embodiment of the present disclosure may have an oblique shape (or a slanted shape or a diagonal shape). Except that each of the first and second getter patterns 191 and 193 has the oblique shape, the light emitting display apparatus according to another embodiment of the present disclosure is a same as and may have a same effect as the light emitting display apparatus described above with reference to FIGS. 1 to 6. Therefore, repetitive descriptions are omitted.

According to another embodiment of the present disclosure, each of the first and second getter patterns 191 and 193 may have an oblique shape. For example, each of the first and second getter patterns 191 and 193 may have a non-linear shape, an oblique shape (or a slanted shape), or a diagonal shape. Each of the plurality of first and second getter patterns 191 and 193 may be disposed in parallel along the diagonal direction in the bending area BA on the substrate 100. Each of the plurality of first getter patterns 191 may be in contact with an adjacent second getter pattern 193. Side surfaces of each of the plurality of first getter patterns 191 may be in contact with side surfaces of adjacent second getter patterns 193. For example, the plurality of second getter patterns 193 may be inserted between the plurality of first getter patterns 191.

According to another embodiment of the present disclosure, each of the first and second getter patterns 191 and 193 has the oblique shape, so that moisture generated in a subsequent cleaning process may be more easily discharged to an outside. Accordingly, the light emitting display apparatus according to another embodiment of the present disclosure may more prevent hydrogen and moisture penetrating into the display panel.

Accordingly, another embodiment of the present disclosure may more prevent corrosion and damage to the thin film transistor and the metal lines (or metal wires) inside the display panel, and more improve the reliability of the light emitting display apparatus.

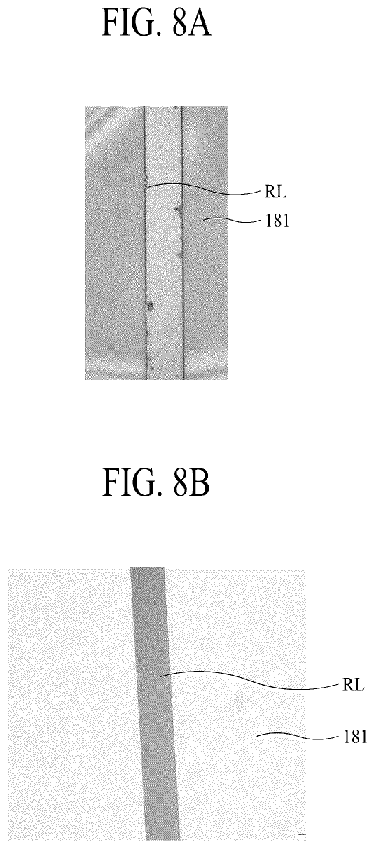

FIGS. 8A and 8B are diagrams illustrating the results of corrosion evaluation of the bending area of the light emitting display apparatus according to the experimental example and the embodiment of the present disclosure. FIG. 8A is an image illustrating the results of a corrosion evaluation of a bending area of a light emitting display apparatus according to an experimental example, and FIG. 8B is an image illustrating the results of a corrosion evaluation of a bending area of the light emitting display apparatus according to an embodiment of the present disclosure.

The inventors of the present disclosure prepared samples as an experimental example and the embodiment example for the evaluation of corrosion in the bending area of each of the light emitting display apparatus according to the embodiment of the present disclosure and the experimental example. The experimental example is corrosion evaluation data for the light emitting display apparatus in which a getter layer is not formed at a bending area. The embodiment example is corrosion evaluation data for the light emitting display apparatus in which a getter layer is formed at a bending area described above with reference to FIGS. 1 to 6. Each of the experimental example and the embodiment example was exposed for 100 hours at a temperature of 65° C. and a humidity of 93%, and a surface of the routing line was measured by SEM.

Referring to FIG. 8A and FIG. 8B, under a same evaluation conditions, it was confirmed that corrosion occurred in the routing line at the bending area according to the experimental example, and no corrosion occurred in the routing line at the bending area according to the embodiment example.

Accordingly, it was confirmed that the light emitting display apparatus according to the embodiment of the present disclosure may prevent hydrogen or moisture from penetrating into the display panel and prevent corrosion of routing lines (or wirings into the display panel) into the display panel by including the getter layer configured at the bending region.

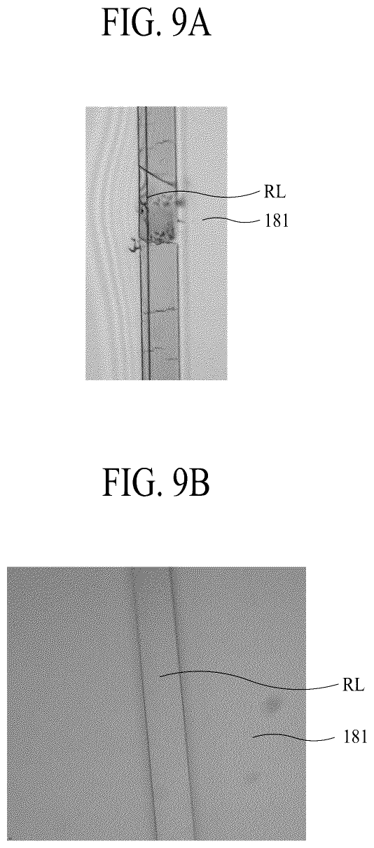

FIGS. 9A and 9B are diagrams illustrating the results of evaluation of bending stress in a bending area of a light emitting display apparatus according to an experimental example and an embodiment of the present disclosure. FIG. 9A is an image evaluating the bending stress of a bending area of a light emitting display apparatus according to an experimental example, and FIG. 9B is an image evaluating the bending stress of a bending area of the light emitting display apparatus according to an embodiment of the present disclosure.

The inventors of the present disclosure prepared samples as an experimental example and the embodiment example for the evaluation of the bending stress of the bending area of each of the light emitting display apparatus according to the embodiment of the present disclosure and the experimental example. The experimental example was manufactured by forming link wiring and an organic layer on a substrate, and the embodiment example was manufactured by forming link wiring, an organic layer, and a getter layer on a substrate. One end and the other end of each of the prepared experimental examples and the prepared embodiment example were connected to a tensile test apparatus, and tension was applied from both sides at a speed of 0.6 mm/min. In addition, a surface of the routing line was measured by SEM.

Referring to FIGS. 9A and 9B, cracks or breakage of the routing line occurred at the point when the sample according to the experimental example was by 2.5 mm tension. In the embodiment example, no cracks or breakage occurred at the point of 2.5 mm tension.

Accordingly, it was confirmed that the light-emitting display apparatus according to the embodiment of the present disclosure may prevent hydrogen or moisture from penetrating into the display panel and prevent cracks from occurring in the lines into the display panel by including a getter layer configured in the bending region. For example, corrosion may occur more through cracks. The embodiment example of the present disclosure has the effect of preventing corrosion by preventing cracks from occurring in the lines.

The light emitting display apparatus according to one or more embodiments of the present disclosure may be described as follows.

The light emitting display apparatus according to one or more embodiments of the present disclosure may comprise a substrate; a display area, a first non-display area surrounding the display area, and a bending area extended from at least a portion of the first non-display area; a pixel part having a plurality of pixels in the display area; a touch sensor layer over the pixel part; and a getter layer configured at the bending area. The getter layer may comprise a plurality of first getter patterns, and a plurality of second getter patterns configured between the plurality of first getter patterns and made of a material different from the plurality of first getter patterns.

According to one or more embodiments of the present disclosure, each of the plurality of first getter patterns may include an inorganic material. Each of the plurality of second getter patterns may include a metal material.

According to one or more embodiments of the present disclosure, the light emitting display apparatus may further comprise an encapsulation layer interposed between the pixel part and the touch sensor layer, and a touch buffer layer interposed between the encapsulation layer and the touch sensor layer. Each of the plurality of first getter patterns may include a same material as the touch buffer layer.

According to one or more embodiments of the present disclosure, the touch sensor layer may include a plurality of touch electrodes, and each of the plurality of second getter patterns may include a same material as the plurality of touch electrodes.

According to one or more embodiments of the present disclosure, the light emitting display apparatus may further comprise a display driving circuit disposed at the bending area and electrically connected to the plurality of pixels through a plurality of routing lines. The bending area may comprise a first organic layer disposed on the substrate, a second organic layer disposed on the first organic layer and covering the plurality of routing lines, and a third organic layer disposed on the second organic layer. The getter layer may be configured on the third organic layer.

According to one or more embodiments of the present disclosure, the pixel part may include a bank layer configured to define an opening area of each of the plurality of pixels, and the third organic layer may include a same material as the bank layer.

According to one or more embodiments of the present disclosure, the pixel part may include a bank layer configured to define an opening area of each of the plurality of pixels, the bank layer may be additionally formed at the bending area. The getter layer may be configured over the bank layer which is formed at the bending area.

According to one or more embodiments of the present disclosure, each of the plurality of first getter patterns and the plurality of second getter patterns may have a line shape.

According to one or more embodiments of the present disclosure, each of the plurality of first getter patterns and the plurality of second getter patterns may have an oblique shape.

According to one or more embodiments of the present disclosure, the plurality of second getter patterns configured between the plurality of first getter patterns may be configured to be in contact with the plurality of first getter patterns.

According to one or more embodiments of the present disclosure, the plurality of second getter patterns configured between the plurality of first getter patterns may be configured to be inserted into the plurality of first getter patterns.

According to one or more embodiments of the present disclosure, each of the plurality of first getter patterns and the plurality of second getter patterns may be spaced apart from the display area.

According to one or more embodiments of the present disclosure, each of the plurality of first getter patterns and the plurality of second getter patterns may be not configured at the first non-display area.

According to one or more embodiments of the present disclosure, the light emitting display apparatus may further include an extension area extending from at least a portion of the bending area. Each of the plurality of first getter patterns and the plurality of second getter patterns may be configured between the first non-display area and the extension area.

According to one or more embodiments of the present disclosure, the light emitting display apparatus may further include an extension area extending from at least a portion of the bending area. End portions of each of the plurality of first getter patterns and the plurality of second getter patterns may be spaced apart from the extension area.

According to one or more embodiments of the present disclosure, the plurality of first getter patterns and the plurality of second getter patterns may have a same height.

The display apparatus according to an embodiment of the present disclosure may be applied to in mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theatre apparatuses, theatre display apparatuses, TVs, wall paper display apparatuses, signage apparatuses, game machines, notebook computers, monitors, cameras, camcorders, and home appliances, or the like.

The description herein has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The description herein and the accompanying drawings provide examples of the technical features of the present disclosure for illustrative purposes. In other words, the disclosed embodiments are intended to illustrate the scope of the technical features of the present disclosure. Thus, the scope of the present disclosure is not limited to the embodiments shown, but is to be accorded the widest scope consistent with the claims. The scope of protection of the present disclosure should be construed based on the following claims, and all technical features within the scope of equivalents thereof should be construed as being included within the scope of the present disclosure.

What is claimed is:

1. A light emitting display apparatus, comprising:
a substrate;
a display area, a first non-display area surrounding the display area, and a bending area extended from at least a portion of the first non-display area;
a pixel part having a plurality of pixels in the display area;
a touch sensor layer over the pixel part; and
a getter layer configured at the bending area,
wherein the getter layer comprises:
a plurality of first getter patterns; and
a plurality of second getter patterns configured between the plurality of first getter patterns and made of a material different from the plurality of first getter patterns.

2. The light emitting display apparatus of claim 1, wherein:
each of the plurality of first getter patterns includes an inorganic material; and
each of the plurality of second getter patterns includes a metal material.

3. The light emitting display apparatus of claim 1, further comprising:
an encapsulation layer interposed between the pixel part and the touch sensor layer; and
a touch buffer layer interposed between the encapsulation layer and the touch sensor layer,
wherein each of the plurality of first getter patterns includes a same material as the touch buffer layer.

4. The light emitting display apparatus of claim 1, wherein:
the touch sensor layer includes a plurality of touch electrodes; and
each of the plurality of second getter patterns includes a same material as the plurality of touch electrodes.

5. The light emitting display apparatus of claim 1, further comprising a display driving circuit disposed at the bending area and electrically connected to the plurality of pixels through a plurality of routing lines,
wherein the bending area comprises:
a first organic layer disposed on the substrate;
a second organic layer disposed on the first organic layer and covering the plurality of routing lines; and
a third organic layer disposed on the second organic layer, and
wherein the getter layer is configured on the third organic layer.

6. The light emitting display apparatus of claim 5, wherein:
the pixel part includes a bank layer configured to define an opening area of each of the plurality of pixels; and
the third organic layer includes a same material as the bank layer.

7. The light emitting display apparatus of claim 1, wherein:
the pixel part includes a bank layer configured to define an opening area of each of the plurality of pixels;
the bank layer is additionally formed at the bending area; and
the getter layer is configured over the bank layer which is formed at the bending area.

8. The light emitting display apparatus of claim 1, wherein each of the plurality of first getter patterns and the plurality of second getter patterns has a line shape.

9. The light emitting display apparatus of claim 1, wherein each of the plurality of first getter patterns and the plurality of second getter patterns has an oblique shape.

10. The light emitting display apparatus of claim 1, wherein the plurality of second getter patterns configured between the plurality of first getter patterns are configured to be in contact with the plurality of first getter patterns.

11. The light emitting display apparatus of claim 1, wherein the plurality of second getter patterns configured between the plurality of first getter patterns are configured to be inserted into the plurality of first getter patterns.

12. The light emitting display apparatus of claim 1, wherein each of the plurality of first getter patterns and the plurality of second getter patterns is spaced apart from the display area.

13. The light emitting display apparatus of claim 1, wherein each of the plurality of first getter patterns and the plurality of second getter patterns is not configured at the first non-display area.

14. The light emitting display apparatus of claim 1, further comprising:
an extension area extending from at least a portion of the bending area,
wherein each of the plurality of first getter patterns and the plurality of second getter patterns is configured between the first non-display area and the extension area.

15. The light emitting display apparatus of claim 1, further comprising:
an extension area extending from at least a portion of the bending area,
wherein end portions of each of the plurality of first getter patterns and the plurality of second getter patterns are spaced apart from the extension area.

16. The light emitting display apparatus of claim 1, wherein the plurality of first getter patterns and the plurality of second getter patterns have a same height.
